(19) United States
(12) Patent Application Publication
(10) Pub. No.: US 2024/0313039 A1
(43) Pub. Date: Sep. 19, 2024

(54) LIGHT EMITTING DEVICE

(71) Applicant: ams-OSRAM International GmbH, Regensburg (DE)

(72) Inventors: Roland Schulz, Regensburg (DE); Aimi Abass, Regensburg (DE); Peter Stauss, Stephanskirchen (DE)

(21) Appl. No.: 18/674,337

(22) Filed: May 24, 2024

Related U.S. Application Data
(63) Continuation of application No. PCT/EP2023/077769, filed on Oct. 6, 2023.

(30) Foreign Application Priority Data
Oct. 6, 2022 (DE) 102022125869.6

(51) Int. Cl. H01L 27/15

(52) U.S. Cl. CPC H01L 27/156

(57) ABSTRACT

In an embodiment a light emitting device includes a semiconductor layer stack with a first layer of a first doping type, a second layer of a second doping type, and an active region arranged between the first and the second layer, a first electric contact connected to an electric contact via, the electric contact via extending electrically isolated through the second layer and the active region and contacting the first layer and a second electric contact contacting the second layer, wherein the first electric contact and the second electric contact are arranged on the second layer on a bottom surface of the semiconductor layer stack, and wherein an interface between a top surface of the semiconductor layer stack and a medium above the top surface is roughened in an area smaller than an area of the top surface.

### CROSS-REFERENCE TO RELATED APPLICATIONS

This patent application is a bypass continuation of PCT/EP2023/077769, filed Oct. 6, 2023, which claims the priority of German patent application 10 2022 125 869.6, filed Oct. 6, 2022, each of which is incorporated herein by reference in its entirety.

### TECHNICAL FIELD

The present invention concerns a light emitting device, in particular a μLED or a pitch of μLEDs with a common converter layer arranged on top, wherein the light emitting device provides an improved contrast performance of the emitted light per pixel and a reduced crosstalk between neighbouring pixel compared to known light emitting device.

### BACKGROUND

With decrease in size of light emitting devices due to the desire of providing displays with ever-increasing resolution and thus an ever-decreasing pixel pitch (typically <40 μm) of the pixels of a light emitting device, cross-talk between neighbouring pixels can significantly increase due to light diffusing through for example a converter layer arranged on top of a light emitting device and/or to a poor contrast performance of the pixels of the light emitting device. This is as implementing a perfect singulation of separate pixels of the light emitting device, typically can only be easily done up till the epi layer but not through a converter layer arranged on top of the light emitting device when one considers pixels <40 μm in pitch. At this size range, the converter layer has thus to be left unsingulated due to fabrication limitations and thus covers several pixels as a common converter or protrudes single pixels. An unsingulated converter layer covering several pixels as a common converter or protruding single pixels can however lead to above mentioned cross-talk and a poor contrast performance.

In addition, light emitting devices with pixels arranged in an array <40 μm in pitch (stitching small “monolithic” pixel in arrays of e.g. 5×5 pixels) tend to have an illuminance inhomogeneity between “inner” pixels and of “rim” pixels at the stitching trench.

It is thus an object of the present application to counteract at least one of the aforementioned problems and to provide a light emitting device with an enhanced contrast performance.

### SUMMARY

This and other objects are addressed by the subject matter of the independent claim. Features and further aspects of the proposed principle are outlined in the dependent claims.

The concept, the inventors propose, is to physically reduce the area where light escapes from the epi structure of a pixel of a light emitting device, for example into the environment or a converter layer, by introducing outcoupling textures within only a central region of the interface between the pixels' epi surface and the environment or the converter layer. By doing so, the area where light escape from a pixel is limited effectively without actually reducing the physical area where current flows, thus avoiding current crowding related problems. Utilizing this approach, one can therefore more easily fulfil forward voltage requirements and avoiding current crowding effects that may significantly reduce Internal Quantum Efficiency (IQE) which would happen if one would physically reduce the pixel size. Only selectively texturing the central region of the interface between the pixel's epi surface and the environment or the converter layer also allows more flexibility in ensuring illuminance homogeneity in pixel arrays constructed by stitching sets of multiple pixels together.

In one aspect, a light emitting device is provided comprising a semiconductor layer stack with a first layer of a first doping type, a second layer of a second doping type, and an active region arranged between the first and the second layer. The light emitting device further comprises a first electric contact connected to an electric contact via, said electric contact via extending electrically isolated through the second layer and the active region and contacting the first layer, and a second electric contact contacting the second layer, first and second electric contacts being arranged on the second layer on a bottom surface of the semiconductor layer stack. To provide, that the area where light escapes from the semiconductor layer stack into the environment or for example a converter layer is an area smaller than a top surface of the semiconductor layer stack, an interface between the first layer and a medium above the top surface of the semiconductor layer stack is roughened in an area smaller than the area of the top surface, in particular at least 10% smaller than the area of the top surface. By this the area where light escapes from the semiconductor layer stack into the medium, for example the environment or a converter layer, is limited effectively to increase the contrast performance of the light emitting device.

In some embodiments, the medium is a converter layer arranged on the first layer on the top surface of the semiconductor layer stack being configured to convert light of a first wavelength generated in the active region into light of a second wavelength. The medium can however also be the environment surrounding the light emitting device as for example air.

The roughened interface can for example be distant from the circumference of the top surface, and in particular be arranged in a central area above the active region. The term “central” area shall in this context however not be understood as the roughened interface is to be arranged in the very centre of the top surface but can also be located distant from the circumference of the top surface with for example different distances to for example opposing edges of the top surface.

In some embodiments, the interface between the first layer and the environment or the converter layer is roughened in a central area above the active region wherein the central region is at least 5%, 10%, or 15% smaller than a projection of the active region when viewing in a direction perpendicular to the top surface.

In some embodiments, the roughened interface provides a better outcoupling of light, generated in the active region, from the top surface into the environment or the converter layer compared to an unroughened interface surrounding the roughened interface. By this the area where light escapes from the semiconductor layer stack into the environment or the converter layer is limited effectively. The unroughened interface can at the same time due to different refractive indexes of the semiconductor layer stack and the environment or the converter layer act as a reflector, in particular for light incident on the top surface at shallow angles. This can in addition further promote the effect of limiting the area where light escapes from the semiconductor layer stack into the environment or the converter layer.

To further promote the effect of limiting the area where light escapes from the semiconductor layer stack into the environment or the converter layer a coating can be arranged on the top surface surrounding the roughened interface, the coating comprising a higher transmission for light incident on the coating perpendicular to the top surface than light incident on the coating at a shallower angle relative to the top surface. The coating can in particular be configured to transmit light incident on the coating perpendicular to the top surface and absorb or reflect light incident on the coating at a shallower angle relative to the top surface, to suppress an emission of light “to the sides” of the light emitting device but transmit an emission of light in a direction substantially perpendicular to the top surface. By this again the area where light escapes from the semiconductor layer stack into the environment or the converter layer is limited effectively to increase the contrast performance of the light emitting device.

In some embodiments, a reflective sidewall is arranged on at least one side surface of the semiconductor layer stack, the side surface connecting the top and the bottom surface with each other. The reflective sidewall or several reflective sidewalls can in particular surround/enclose the semiconductor layer stack and can thus be arranged on all side surfaces of the semiconductor layer stack. The reflective sidewall can be configured to reflect light generated in the active region in the direction of the top surface, to enhance the light emitting efficiency of the light emitting device. In addition, the reflective sidewall can be configured to reflect light, reflected at the unroughened surface or the coating, to the roughened surface to again enhance the light emitting efficiency of the light emitting device and to ensure that the light blocked at the first moment by the unroughened surface or the coating nevertheless finds its way out of the light emitting device via the roughened interface.

In some embodiments, a reflective layer is arranged on the bottom surface of the layer stack, the reflective layer surrounding the first and the second electric contacts. The reflective layer can be configured to reflect light generated in the active region in the direction of the top surface, to enhance the light emitting efficiency of the light emitting device. In addition, the reflective layer can be configured to reflect light, reflected at the unroughened surface or the coating, to the roughened surface to again enhance the light emitting efficiency of the light emitting device and to ensure that the light blocked at the first moment by the unroughened surface or the coating nevertheless finds its way out of the light emitting device via the roughened interface.

A possible output luminance penalty compared to providing an outcoupling structure over the whole top surface of the light emitting device can in particular be minimized by improving the reflectivity of the side surfaces of the semiconductor layer stack and/or the bottom surface of the semiconductor layer stack. The reflectivity of the reflective side wall(s) and/or the reflective layer can for example be improved by choosing a less lossy material for the side wall(s) (for example aluminium or silver) and additionally applying a single-layer coating (e.g. SiO₂) that is thick enough to allow total internal reflectance with minimal loss. As an alternative, a multilayer coating that functions as a distributed Bragg mirror can be applied to improve the reflectance over all incoming angles.

In some embodiments, at least the second layer and the active region is separated into a first and at least a second portion of the semiconductor layer stack each forming a pixel of the light emitting device. The first and at least second portion can in particular be formed by a trench etched into the semiconductor stack, the trench extending at least through the second layer and the active region, as well as optionally through a portion of the first layer or through the whole first layer. The first and at least second portion can in particular be arranged adjacent to each other and in case of more than two portions be arranged in an array corresponding to a pixel pitch of the light emitting device. The trench can in some embodiments be filled with a reflective separator, wherein the reflective separator can be similar to above described sidewall(s).

The first and the at least second portion can however also be separated by the electric contact via, hence the electric contact via filling the trench separating the first and the at least second portion from each other. In case of the first and the at least second portion being separated by the electric contact via, the trench may in a preferred embodiment extend through the second layer and the active region, as well as through a portion of the first layer, such that the electric contact via contacts the first layer. The first layer may thus comprise a portion, which is not completely separated but still connects the first and at least second portion of the semiconductor layer stack providing a common electric contact for the portions of the layer stack.

In some embodiments, above each the first and the at least second portion the interface between the first layer and the environment or the converter layer is roughened in a separate area, the separate areas being spaced from each other. In other words, each pixel of the light emitting device is associated with its own roughened interface area limiting the area where light escapes from the respective pixel of the light emitting device into the environment or the common converter layer thus improving the contrast performance of the light emitting device.

In some embodiments, the top surface is theoretically divided into surface areas, one surface area of each of which is assigned to the first and the at least second portion, and wherein the separate roughened interface areas are each located within the theoretically divided surface areas each distant from the circumference of the respective surface area.

In some embodiments, the separate roughened interface areas are further distant from a neighbouring edge of neighbouring surface areas than from the opposing edge of the respective surface area. In particular the separate roughened interface areas are further distant from “inner” edges of the surface areas than from “outer” edges of the surface areas, wherein the “outer” edges of the surface areas are closer to the side surfaces of the semiconductor layer stack than the “inner” edges. This results in the pixel illuminance of the light emitting device is more homogeneous over “inner” pixels as well as “rim” pixels.

In some embodiments, each a second electric contact contacts the separate portions of the second layer of the first and the at least second portion. Hence, each pixel of the light emitting device comprises its own separate electric contact on the one side of the semiconductor layer stack as well as in particular a common electric contact on the other side of the semiconductor layer stack. Each pixel of the light emitting device can thus be separately electrically controllable.

In some embodiments, the light emitting device or the pixels of the light emitting device are formed by an LED, in particular an LED chip. In particular, an LED may be referred to as a μLED. A μLED is a small LED, for example with edge lengths of less than 100 μm, in particular less than 40 μm, and in particular in the range of 40 μm to 5 μm. Another range is between 100 μm to 10 μm. At these spatial extents, the optoelectronic semiconductor device is virtually invisible to the human eye.

In some embodiments, the μLED or μLED chip may be an unhoused semiconductor chip. Unhoused means that the chip does not have a package around its semiconductor layers, such as a “chip die”. In some embodiments, unhoused may mean that the chip is free of any organic material. Thus, the unhoused device does not contain any organic compounds that contain carbon in a covalent bond.

### BRIEF DESCRIPTION OF THE DRAWINGS

Further aspects and embodiments in accordance with the proposed principle will become apparent in relation to the various embodiments and examples described in detail in connection with the accompanying drawings in which

FIG. 1 shows a light emitting device with an outcoupling structure over the whole top surface of the light emitting device;

FIG. 2 illustrates a light emitting device in accordance with some aspects of the proposed principle;

FIG. 3 shows another embodiment of a light emitting device in accordance with some aspects of the proposed principle;

FIG. 4 illustrates a further embodiment of a light emitting device in accordance with some aspects of the proposed principle;

FIG. 5A a top view of an embodiment of a light emitting device in accordance with some aspects of the proposed principle; and

FIG. 5B a top view of a further embodiment of a light emitting device in accordance with some aspects of the proposed principle.

### DETAILED DESCRIPTION OF ILLUSTRATIVE EMBODIMENTS

The following embodiments and examples disclose various aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

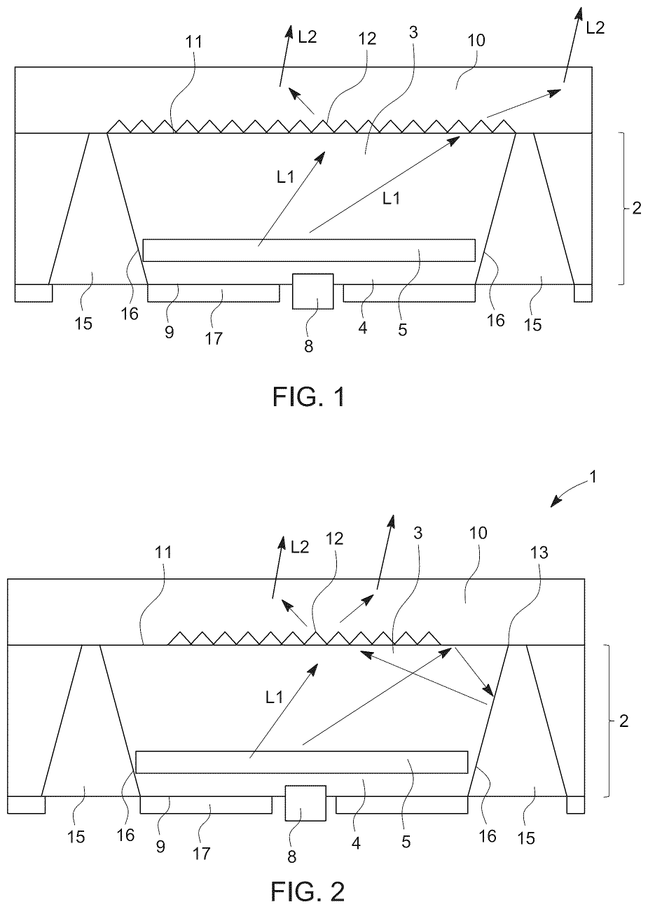

FIG. 1 shows a sketch of a reference pixel of a light emitting device with an outcoupling structure over the whole top surface 11 of a semiconductor layer stack 2. Light L2 that escapes from a converter layer 10 arranged on the semiconductor stack of the light emitting device at the edges of a pixel typically leaks to neighbouring pixels (see L2 on the right of the FIG. 1) resulting in cross-talk between the neighbouring pixels and/or in a poor contrast performance of the pixel of the light emitting device.

However, if light extraction into the converter layer 10 at the edges of the pixel can be minimized, cross-talk between neighbouring pixels would be reduced and thus a higher contrast performance of the pixel could be achieved.

The inventors therefore propose to limit the outcoupling structure at the interface between the semiconductor layer stack 2 and the converter layer to a central area above a pixel of the light emitting device, to allow light L2 to be emitted from the light emitting device in only a central area of the pixel of the light emitting device.

FIG. 2 shows a respective light emitting device 1 comprising a semiconductor layer stack 2 with a first layer 3 of a first doping type, a second layer 4 of a second doping type, and an active region 5 arranged between the first and the second layer. The light emitting device 1 further comprises a first electric contact connected to an electric contact via (both not shown here), said electric contact via extending electrically isolated through the second layer 4 and the active region 5 and contacting the first layer 3. In addition, a second electric contact 8 is contacting the second layer and is as the not shown first electric contact arranged on the second layer 4 on a bottom surface 9 of the semiconductor layer stack 2. On the first layer 3 on a top surface 11 of the semiconductor layer stack 2, a converter layer 10 is arranged, wherein the converter layer 11 is configured to convert light of a first wavelength L1 generated in the active region 5 into light of a second wavelength L2.

To provide, that the area where light escapes from the semiconductor layer stack 2 into the converter layer 10 is an area smaller than the top surface 11 of the semiconductor layer stack 2, an interface 12 between the first layer 3 and the converter layer 10 is roughened in an area smaller than the area of the top surface 11. By this the area where light escapes from the semiconductor layer stack 2 into the converter layer 10 is limited effectively to increase the contrast performance of the light emitting device 1. The roughened interface 12 is in particular distant from the circumference 13 of the top surface 11, and in particular arranged in a central area above the active region 5.

The limitation of the roughened interface 12 to an area smaller than the area of the top surface 11 effects as shown in FIG. 2 that light L1 incident on the unroughened interface surrounding the roughened interface 12 is reflected back into the semiconductor layer stack 2 and in comparison to the light emitting device of FIG. 1 does not escapes from the converter layer 10 at the edges of the pixel of the light emitting device 1 shown. This is as the roughened interface 12 provides a better outcoupling of light, generated in the active region 5, from the top surface 11 into the converter layer 10 compared to the unroughened interface surrounding the roughened interface 12 due to different refractive indexes of the semiconductor layer stack 2 and the converter layer 10 at the unroughened interface. The unroughened interface thus acts as a reflector, in particular for light incident on the top surface 11 at shallow angles.

To however ensure that the back reflected light at the unroughened interface still escapes from the light emitting device, reflective sidewalls 15 at the side surfaces 16 of the semiconductor layer stack 2 as well as a reflective layer 17 arranged on the bottom surface 9 of the semiconductor layer stack 2 are provided to guide the back reflected light in the direction of the roughened interface 12 (see the arrows on the right of FIG. 2).

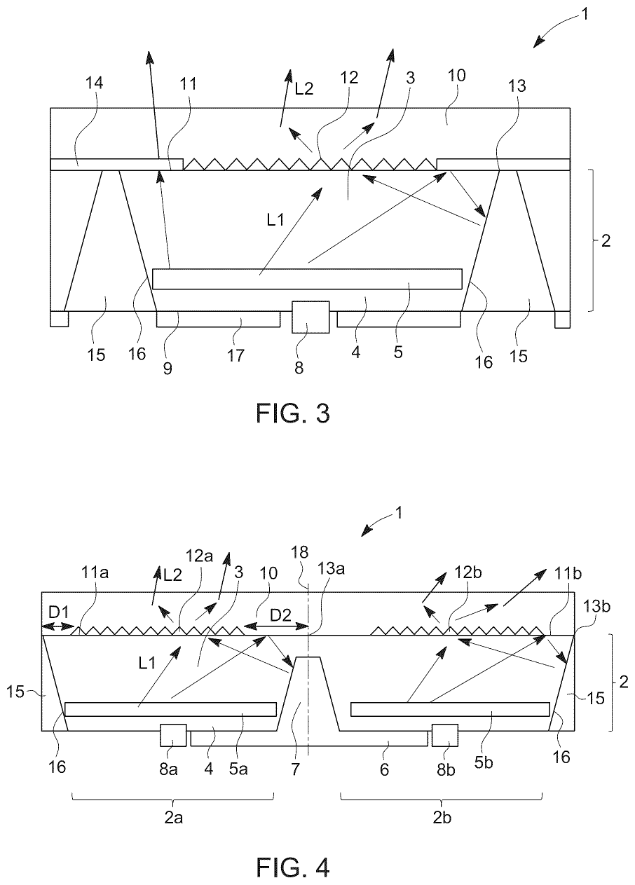

FIG. 3 shows a further embodiment of the light emitting device 1, which in addition to the embodiment of FIG. 2 comprises a coating 14 on the top surface 11 surrounding the roughened interface 12. The coating 14 comprises a higher transmission for light incident on the coating 14 substantially perpendicular to the top surface 11 (see left arrows of FIG. 3) than light incident on the coating 14 at a shallower angles relative to the top surface 11 (see right arrows of FIG. 3). By this an emission of light “to the sides” of the light emitting device 1 can further be reduced but an emission of light in a direction substantially perpendicular to the top surface 11 can be allowed. By this again the area where light escapes from the semiconductor layer stack 2 into the converter layer 10 is limited effectively to increase the contrast performance of the light emitting device 1. The coating 14 can for example be a thin-film (multilayer) coating to manage the optical response at the unroughened interface to improve contrast or light extraction further by reducing the transmittance in this region for a particular angular or wavelength range and increasing the same for another particular angular or wavelength range. The coating 14 can for example be a interference filter or a dichroic filter or the like.

FIG. 4 shows a further embodiment of a light emitting device comprising several pixels arranged next to each other as well as a common converter layer 10 arranged on the pixels. Such a design can for example be called a so called “cloverleaf” design where for example 4 pixels are connected to each other like a cloverleaf.

To form the pixels, the semiconductor layer stack 2, and in particular the second layer 4, the active region 5 and part of the first layer 3 is separated into separate portions 2a, 2b, . . . of the semiconductor layer stack 2 each forming a pixel of the light emitting device 1. The separate portions 2a, 2b, . . . can in particular be formed by a trench etched into the semiconductor stack 2, the trench extending through the second layer 4 and the active region 5, as well as through part of the first layer 3. Each separate portion 2a, 2b, . . . and thus each pixel comprises its own active region 5a, 5b, . . . to generate light L1 when being excited.

The separate portions 2a, 2b, . . . are separated by the electric contact via 7, hence the electric contact 7 via filling the trench separating the portions 2a, 2b, . . . from each other. The electric contact via thereby contacts the first layer 3, wherein the first layer 3 comprises a portion, which is not completely separated but still connects the separate portions 2a, 2b, . . . of the semiconductor layer stack 2 providing a common electric contact for the portions 2a, 2b, . . . of the semiconductor layer stack 2. On the electric contact 7 on the bottom surface 9 of the semiconductor layer stack a first electric contact is arranged by which the pixels can be controlled in combination with second electric contacts 8a, 8b, . . . on the bottom surface 9 of each of the separate portions 2a, 2b, . . . of the semiconductor layer stack 2. Hence, each pixel of the light emitting device 2 comprises its own separate second electric contact 8a, 8b, . . . on the one side of the semiconductor layer stack 2 as well as a common electric contact on the other side of the semiconductor layer stack 2. Each pixel of the light emitting device 1 is thus separately electrically controllable.

Above each separate portion 2a, 2b, . . . and thus above each pixel, the interface between the first layer 3 and the converter layer 10 is roughened in a separate area 12a, 12b, . . . , wherein the roughened interface areas 12a, 12b, . . . are spaced from each other. Hence, each pixel of the light emitting device 1 is associated with its own roughened interface area 12a, 12b, . . . limiting the area where light escapes from the respective pixel of the light emitting device into the common converter layer 10 thus improving the contrast performance of the light emitting device 1.

The top surface 11 is theoretically divided into surface areas 11a, 11b, . . . , one surface area of each of which is assigned to the separate portions 2a, 2b, . . . of the semiconductor layer stack 2. The theoretical division is performed along the dividing line/plane 18 through the semiconductor layer stack 2 between two adjacent pixels. The separate roughened interface areas 12a, 12b, . . . are each located within the theoretically divided surface areas 11a, 11b, . . . each distant from the circumference 13a, 13b, . . . of the respective surface area 11a, 11b, . . . .

As shown in FIG. 4, the separate roughened interface areas 12a, 12b, . . . are further distant (distance D2) from a neighbouring edge of neighbouring surface areas than from the opposing edge of the respective surface area (distance D1). In particular the separate roughened interface areas 12a, 12b, . . . are further distant from “inner” edges (distance D2) of the surface areas than from “outer” edges (distance D1) of the surface areas, wherein the “outer” edges of the surface areas are closer to the side surfaces 16 of the semiconductor layer stack 2 than the “inner” edges. This results in the pixel illuminance of the light emitting device is more homogeneous over “inner” pixels as well as “rim” pixels. In FIG. 4 this is indicated by the distances D1 and D2, where D1 is the distance from the outer edge of the light emitting device to the roughened interface of one of the pixels and D2 is the distance from the inner edge or the dividing line/plane 18 the roughened interface of the pixel.

The embodiments shown in FIGS. 2 and 3 are however only to be understood as exemplary embodiments and can similarly to the embodiment shown in FIG. 4 be extended to its left or right to form an array of pixels arranged next to each other with a common converter layer arranged on top of the pixels.

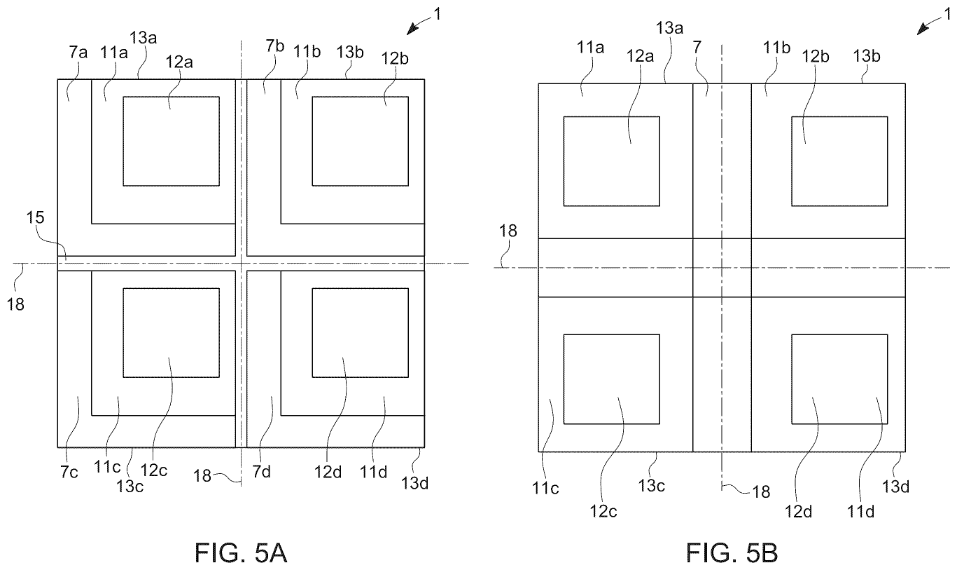

FIGS. 5A and 5B each show a top view of an embodiment of a light emitting device in accordance with some aspects of the proposed principle, and in particular a light emitting device comprising several pixels arranged next in a cloverleaf design.

FIG. 5A shows an embodiment, where each separate portion 2a, 2b, . . . of the semiconductor layer stack 2 is assigned with its own contact via 7a, 7b, . . . along two edges of the respective separate portion 2a, 2b, . . . . The separate portions 2a, 2b, . . . are in the embodiment shown divided by a reflective sidewall 15 in a cross-like manner, the reflective sidewall 15 extending throughout the whole semiconductor layer stack 2 completely separating the first layer, the second layer and the active region from each other. The top surface 11 of the semiconductor layer stack 2 is theoretically divided into the surface areas 11a, 11b, . . . , along the dividing lines/planes 18, and the separate roughened interface areas 12a, 12b, . . . are each located within the theoretically divided surface areas 11a, 11b, . . . each distant from the circumference 13a, 13b, . . . of the respective surface area 11a, 11b, . . . .

FIG. 5B shows an embodiment, where the separate portions 2a, 2b, . . . of the semiconductor layer stack 2 are electrically connected via a common electric contact by the contact via 7 extending in a cross-like manner through the first layer, the active region, and part of the second layer. The top surface 11 of the semiconductor layer stack 2 is theoretically divided into the surface areas 11a, 11b, . . . , along the dividing lines/planes 18, and the separate roughened interface areas 12a, 12b, . . . are each located within the theoretically divided surface areas 11a, 11b, . . . each distant from the circumference 13a, 13b, . . . of the respective surface area 11a, 11b, . . . .

What is claimed is:

1. A light emitting device comprising:
a semiconductor layer stack with a first layer of a first doping type, a second layer of a second doping type, and an active region arranged between the first and the second layer;
a first electric contact connected to an electric contact via, the electric contact via extending electrically isolated through the second layer and the active region and contacting the first layer;
a second electric contact contacting the second layer; and
a medium,
wherein the first electric contact and the second electric contact are arranged on the second layer on a bottom surface of the semiconductor layer stack, and
wherein an interface between a top surface of the semiconductor layer stack and the medium above the top surface is roughened in an area smaller than an area of the top surface.

2. The light emitting device according to claim 1, wherein the area smaller is at least 10% smaller than the area of the top surface.

3. The light emitting device according to claim 1, wherein the medium above the top surface is a converter layer arranged on the first layer on the top surface of the semiconductor layer stack, and wherein the converter layer is configured to convert light of a first wavelength generated in the active region into light of a second wavelength.

4. The light emitting device according to claim 3, wherein the interface between the first layer and the converter layer is roughened in a central area above the active region, and wherein a central region is at least 10% smaller than a projection of the active region in view of a direction perpendicular to the top surface.

5. The light emitting device according to claim 1, wherein the roughened interface is distant from a circumference of the top surface.

6. The light emitting device according to claim 1, wherein the roughened interface provides a better outcoupling of light from the top surface into a converter layer compared to an unroughened interface.

7. The light emitting device according to claim 1, wherein a coating is arranged on the top surface surrounding the roughened interface, the coating comprising a higher transmission for light incident on the coating perpendicular to the top surface than light incident on the coating at a shallower angle relative to the top surface.

8. The light emitting device according to claim 1, further comprising a reflective sidewall arranged on at least one side surface of the semiconductor layer stack, the side surface connecting the top surface and the bottom surface with each other.

9. The light emitting device according to claim 1, further comprising a reflective layer arranged on the bottom surface of the semiconductor layer stack, the reflective layer surrounding the first and second electric contacts.

10. The light emitting device according to claim 1, wherein at least the second layer and the active region is separated into a first portion and at least a second portion.

11. The light emitting device according to claim 10, wherein the first portion and the at least second portion are separated by the electric contact via.

12. The light emitting device according to claim 10, wherein above each of the first portion and the at least second portion the interface between the first layer and a converter layer is roughened in separate areas, the separate areas being spaced from each other.

13. The light emitting device according to claim 12, wherein the top surface is divided into surface areas, one surface area of each of which is assigned to the first portion and the at least second portion, and wherein the separate roughened interface areas are each distant from a circumference of the respective surface area.

14. The light emitting device according to claim 13, wherein the separate roughened interface areas are further distant from a neighbouring edge of neighbouring surface areas than from an opposing edge of the respective surface area.

15. The light emitting device according to claim 10, wherein each second electric contact contacts the separate portions of the second layer of the first portion and the at least second portion.

16. The light emitting device according to claim 1, wherein the light emitting device comprises at least one μLED.
